(19) United States
(12) Patent Application Publication
(10) Pub. No.: US 2026/0004839 A1
(43) Pub. Date: Jan. 1, 2026

(54) DISTRIBUTED TEMPERATURE SENSORS IN A DIE OF A MEMORY DEVICE

(71) Applicant: Micron Technology, Inc., Boise, ID (US)

(72) Inventors: Elena Cabrera Bernal, Munich (DE); Fabien Funfrock, Munich (DE); Jens Polney, Feldkirchen (DE); Suhas Shivapakash, Munich (DE)

(21) Appl. No.: 19/202,960

(22) Filed: May 8, 2025

Related U.S. Application Data
(60) Provisional application No. 63/666,011, filed on Jun. 28, 2024.

(51) Int. Cl. G11C 11/406; G11C 11/4076; G11C 11/4096

(52) U.S. Cl. CPC G11C 11/40626; G11C 11/4076; G11C 11/4096

(57) ABSTRACT

Methods, systems, and devices for distributed temperature sensors in a die of a memory device are described. For example, the distributed temperature sensors may enable a memory system controller to detect hotspots or uneven temperature distributions across the memory system. The memory system controller may perform health monitoring reporting based on the detected hotspots or uneven temperature distributions. In some examples, the memory system controller may activate, or deactivate, one or more components of regions associated with the hotspots to reduce the temperature of the region or die. Additionally, or alternatively, the memory system controller may adjust or retrain a clock signal to compensate for the detected hotspots or uneven temperature distributions.

### CROSS REFERENCE

The present application for patent claims priority to U.S. Patent Application No. 63/666,011 by Cabrera Bernal et al., entitled “DISTRIBUTED TEMPERATURE SENSORS IN A DIE OF A MEMORY DEVICE,” filed Jun. 28, 2024, which is assigned to the assignee hereof, and which is expressly incorporated by reference in its entirety herein.

### TECHNICAL FIELD

The following relates to one or more systems for memory, including distributed temperature sensors in a die of a memory device.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports distributed temperature sensors in a die of a memory device in accordance with examples as disclosed herein.

FIG. 2 shows an example of an architecture that supports distributed temperature sensors in a die of a memory device in accordance with examples as disclosed herein.

FIGS. 3 and 4 show examples of process flows that support distributed temperature sensors in a die of a memory device in accordance with examples as disclosed herein.

FIG. 5 shows a block diagram of a memory system that supports distributed temperature sensors in a die of a memory device in accordance with examples as disclosed herein.

FIGS. 6 through 8 show flowcharts illustrating a method or methods that support distributed temperature sensors in a die of a memory device in accordance with examples as disclosed herein.

### DETAILED DESCRIPTION

In some memory systems, one or more dies may include a respective temperature sensor. A temperature that exceeds a temperature threshold (e.g., a hotspot) may reduce performance of the memory system (e.g., by increasing a duration to complete write commands) and, in some cases, reduce the life-cycle of the memory system. Temperature data gathered by the sensor may enable a controller of the memory system to provide monitoring reports to a host system and to adjust one or more components of the memory system to reduce the temperature. However, as some memory systems increase in size, a single temperature sensor may not accurately measure or detect the temperature across the memory system. The memory system controller may thus be unaware of hotspots in areas relatively distant (e.g., far away) from the temperature sensor, which may result in the memory system operating at relatively hot temperatures. Thus, it may be beneficial to distribute additional temperature sensors throughout the memory system to increase health monitoring report accuracy, memory system performance, and the life-cycle of the memory system.

The techniques described herein implement multiple temperature sensors distributed throughout a memory system to increase health monitoring report accuracy, performance, and the life-cycle of the memory system. For example, the distributed temperature sensors may enable a memory system controller to detect hotspots or uneven temperature distributions across an interface die of the memory system more accurately relative to conventional methods. The memory system controller may perform health monitoring reporting based on the detected hotspots or uneven temperature distributions. In some examples, the memory system controller may activate, or deactivate, one or more components located in regions associated with the hotspots to reduce the region's temperature.

Additionally, or alternatively, the memory system controller may adjust (e.g., retrain) a clock signal to compensate for the detected hotspots or uneven temperature distributions. For example, a hotspot may increase a propagation delay of the clock signal, which may increase a duration to complete a write command. Adjusting (e.g., retraining) the clock signal may enable the memory system controller to compensate for the increased propagation delay. In addition to the distributed temperature sensors, the memory system controller may also receive temperature information from temperature sensors in stacked memory dies of the memory system (e.g., DRAM dies stacked on the interface die). The temperature information from the distributed temperature sensors and the temperature sensors in the stacked memory dies may enable the memory system controller to improve the overall performance of the memory system and increase its life-cycle by reducing temperatures that exceed a temperature threshold would have otherwise degraded aspects of the memory system.

In addition to applicability in memory systems as described herein, techniques for distributed temperature sensors in a die of a memory device may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by adjusting a clock signal (e.g., a clock tree) of the memory system, which may decrease read and write command completion durations for higher temperatures of the memory system (e.g., higher temperatures may otherwise increase read and write command completion durations in systems without distributed temperature sensors), among other benefits.

In addition to applicability in memory systems as described herein, techniques for distributed temperature sensors in a die of a memory device may be generally implemented to improve the sustainability of various electronic devices and systems. As the use of electronic devices has become even more widespread, the amount of energy used and harmful emissions associated with production of electronic devices and device operation has increased. Further, the amount of waste (e.g., electronic waste) associated with disposal of electronic devices may also pose environmental concerns. Implementing the techniques described herein may improve the impact related to electronic devices by enabling the memory system to perform more accurate health monitoring and adjusting different systems of a die of the memory system to reduce its temperature, which may prevent further degradation of the memory system (e.g., caused by relatively high temperatures) and extend the life-cycle of the memory system, among other benefits.

Features of the disclosure are illustrated and described in the context of systems and architectures. Features of the disclosure are further illustrated and described in the context of architectures, process flows, and flowcharts.

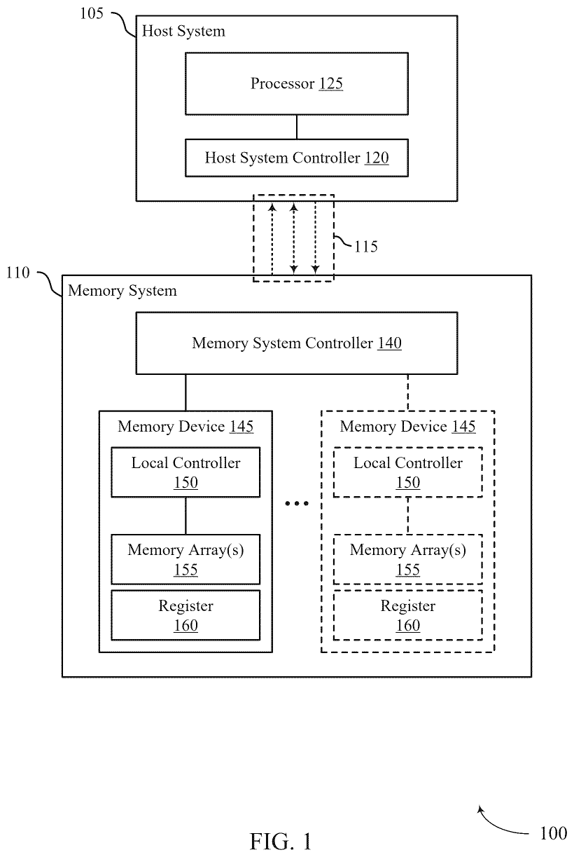

FIG. 1 illustrates an example of a system 100 that supports distributed temperature sensors in a die of a memory device in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (A SIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some memory systems 110, one or more dies of the memory system 110 may include a respective temperature sensor. A temperature that exceeds a temperature threshold (e.g., a hotspot) of the memory system 110 may reduce performance of the memory system 110 (e.g., an increased temperature may increase a duration to complete write commands) and, in some cases, reduce the life-cycle of the memory system 110. Temperature information gathered by the temperature sensor may enable a controller of the memory system (e.g., the memory system controller 140) to provide health monitoring reports to a host system 105 and to adjust one or more components of the memory system 110 to reduce the temperature. However, as some memory systems 110 increase in size, a single temperature sensor may not accurately reflect the temperature across the memory system 110. The memory system controller 140 may be unaware of hotspots in areas relatively distant from the temperature sensor, which may reduce the life-cycle of the memory system 110 and decrease performance. Thus, it may be beneficial to distribute additional temperature sensors throughout the memory system 110 to increase health monitoring report accuracy, memory system performance, and the life-cycle of the memory system 110.

The techniques described herein implement multiple temperature sensors distributed throughout a memory system 110 to increase health monitoring report accuracy, performance, and the life-cycle of the memory system 110. For example, the distributed temperature sensors may enable a memory system controller 140 to detect hotspots or uneven temperature distributions across an interface die of the memory system 110 more accurately relative to conventional methods. The memory system controller 140 may perform health monitoring reporting based on the detected hotspots or uneven temperature distributions. In some examples, the memory system controller 140 may activate, or deactivate, one or more components located in regions associated with the hotspots to reduce the region's temperature.

Additionally, or alternatively, the memory system controller 140 may adjust (e.g., retrain) a clock signal to compensate for the detected hotspots or uneven temperature distributions. For example, a hotspot may increase a propagation delay of the clock signal, which may increase a duration to complete a write command. Adjusting (e.g., retraining) the clock signal may enable the memory system controller 140 to compensate for the increased propagation delay. In addition to the distributed temperature sensors, the memory system controller 140 may also receive temperature information from temperature sensors in stacked memory dies of the memory system 110 (e.g., DRAM dies stacked on the interface die). The temperature information from the distributed temperature sensors and the temperature sensors in the stacked memory dies may enable the memory system controller 140 to improve the overall performance of the memory system 110 and increase its life-cycle by reducing temperatures that exceed a temperature threshold would have otherwise degraded aspects of the memory system 110.

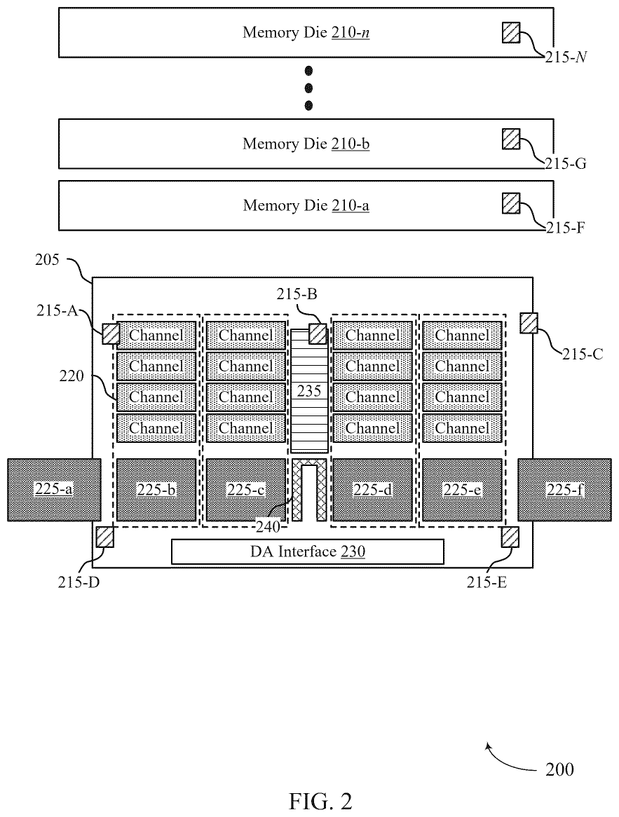

FIG. 2 illustrates an example of an architecture 200 (e.g., a memory architecture) that supports distributed temperature sensors in a die of a memory device in accordance with examples as disclosed herein. The architecture 200 may be implemented in a memory system 110 or one or more components thereof (e.g., memory device 145). Aspects of the architecture 200 may be referred to as or implemented in a semiconductor component, such as a memory die. The architecture 200 may include two or more dies corresponding to one or more memory devices (e.g., a memory device 145). The two or more dies may include an interface die 205 and one or more memory dies 210 (e.g., DRAM dies) stacked above the interface die 205. It may be understood that there may be any quantity (e.g., n quantity) of memory dies 210 stacked above the interface die 205. The architecture 200 may support distributed temperature sensors, which may enable a memory system controller to improve the overall performance of a memory system and increase its life-cycle by reducing temperatures that exceed a temperature threshold would have otherwise degraded aspects of the memory system.

In some examples, the interface die 205 may receive read and write commands from a host system (e.g., a host system 105) and communicate the commands to the one or more memory dies 210 via a memory system controller (e.g., a memory system controller 140). In some examples, the host system may be associated with a graphics processing unit (GPU). Additionally, or alternatively, the memory system controller may manage the distribution of data across the one or more memory dies 210, and perform data management operations on the one or more memory dies (e.g., garbage collection, wear leveling, and the like), among other examples. In some examples, the memory system controller may perform the operations described herein based on temperature information gathered from the temperature sensors 215.

The interface die 205 may include multiple temperature sensors 215 distributed across multiple regions of the interface die 205. The temperature sensors 215 may obtain temperature information of a respective region of the interface die 205. For example, the interface die 205 may include five temperature sensors 215. A first temperature sensor 215-a and a second temperature sensor 215-d may be aligned along a first boundary of the interface die 205, and a third temperature sensor 215-c and a fourth temperature sensor 215-e may be aligned along a second boundary of the interface die 205. A fifth temperature sensor 215-b may be aligned near the center of the interface die 205. For example, the first temperature sensor 215-a, the third temperature sensor 215-c, and the fifth temperature sensor 215-b may be aligned colinearly.

In some examples, the interface die 205 may include more than five temperature sensors. For example, the interface die 205 may include one or more additional temperature sensors 215 along the first boundary, the second boundary, along a center axis of the interface die 205, or any combination thereof. In some examples, the position of the temperature sensors 215 may enable the memory system controller to determine a temperature distribution across the interface die 205. For example, the memory system controller may utilize temperature data from each of the temperature sensors 215 to estimate the temperature distribution. Additionally, or alternatively, a “region” may refer to an area from which a single temperature sensor 215 is able to reliably gather temperature data from.

In some examples, the interface die 205 may include a direct access (DA) interface 230, a testing interface 235 (e.g., a P1500 interface), and one or more vias 240 (e.g., TSV Mid) between the DA interface 230 and testing interface 235. In some examples, the DA interface 230 may support direct communication access to the interface die 205. For example, the DA interface 230 may enable testing and verification of the interface die 205. In some examples, the testing interface 235 may enable the accessing and testing of individual cores connected to the interface die 205.

In some examples, the interface die 205 may manage communications between the host system and the one or more memory dies 210 via one or more channels 220. The channels 220 may be data channels, such as the channels 115 described with reference to FIG. 1. For example, the one or more channels 220 may receive data from the host system (e.g., the GPU) and transmit the data to the one or more memory dies 210 using one or more input/output (I/O) interfaces 225. Additionally, or alternatively, a respective quantity of channels 220 may communicate with a respective I/O interface 225. For example, four channels 220 located between the first temperature sensor 215-a and the I/O interface 225-b may communicate with the I/O interface 225-b.

In some examples, a first subset of the one or more channels 220 may be located between the first temperature sensor 215-a and the fifth temperature sensor 215-b, and a second subset of the channels 220 may be located between the fifth temperature sensor 215-b and the third temperature sensor 215-c. Each subset may be associated with one or more (e.g., two) I/O interface 225. For example, the first subset may be associated with I/O interface 225-b and I/O interface 225-c, and the second subset may be associated with I/O interface 225-d and I/O interface 225-e.

In some examples, the interface die 205 may include a timing circuit. The timing circuit may synchronize the operations of the interface die 205 (e.g., at the channels 220) and the one or more memory dies 210. For example, the timing circuit may generate a clock signal to coordinate read and write operations of data between the one or more channels 220, the I/O interface 225, and the one or more memory dies 210.

In some examples, each of the one or more memory dies 210 may include a respective temperature sensor 215. For example, the memory die 210-a may include a temperature sensor 215-f, the memory die 210-b may include a temperature sensor 215-g, and memory die 210-n may include a temperature sensor 215-n, where n corresponds to the quantity of memory dies 210 stacked on the interface die 205. The memory system controller may receive temperature data from each of the temperature sensors 215 in each of the memory dies 210. In some examples, the memory dies 210 may be stacked above the channels 220 and the I/O interface 225 (e.g., in a vertical direction).

For example, the interface die 205 may receive the temperature data from the memory dies 210 via the I/O interface 225. In some examples, the memory system controller may use the temperature data from the memory dies 210 in addition to the temperature sensors 215-a through 215-e to estimate the temperature distribution of the interface die 205 and a temperature of each of the memory dies 210 (e.g., the memory system controller may create a 3-d picture of the temperature of the memory system).

In some examples, the memory system controller may receive temperature data from each of the temperature sensors 215 periodically (e.g., at a predefined or set cadence). For example, the memory system controller may receive temperature data from each of the temperature sensors 215 such that the temperature data represents the current temperature of the interface die 205, the memory dies 210, or both. Additionally, or alternatively, the memory system controller may receive the temperature data based on a temperature of a respective region of the interface die 205, a temperature of a respective memory die 210, or both, exceeding a threshold temperature.

For example, the memory system controller may determine that a temperature of the interface die 205, at least one of the memory dies 210, or both, exceeds a temperature threshold (e.g., a hotspot occurs in the interface die 205 or in the at least one memory die 210). The temperature of the interface die 205 or the at least one memory die 210 may affect a length of a clock signal from the timing circuit. For example, a temperature above the temperature threshold may affect (e.g., increase or decrease) a propagation delay of the clock signal. Changes in the propagation delay of the clock signal may result in longer durations to complete a write command. For example, the memory system controller may sample data at the wrong time, which may increase the likelihood of errors at the memory system, as well as the duration to complete a write command. In some examples, the memory system controller may transmit a clock tree sensitivity to the host system. For example, the clock tree sensitivity may indicate how sensitive the propagation delay of the clock tree is to a particular temperature (e.g., 1 ps per degree). Additionally, or alternatively, the memory system controller may transmit the determined propagation delay of the clock tree to the host system.

In some examples, the memory system controller may adjust the clock signal based on the temperature of the interface die 205, the at least one memory die 210, or both exceeding the temperature threshold (e.g., based on detecting a hot spot). For example, the memory system controller may adjust one or more timings of the timing circuit to compensate for the propagation delay exceeding the threshold duration. In some examples, the memory system controller may adjust a sampling length of data to be written (e.g., to a memory die 210) to match the sampling length of the clock signal.

Additionally, or alternatively, the memory system controller may adjust the clock tree based on receiving an indication from the host system. The host system may determine to adjust the clock signal based on receiving the clock tree sensitivity indication, and an indication of a temperature of a region of the interface die 205 or the at least one memory die 210 exceeding the temperature threshold. For example, the host system may determine to the adjust the clock tree based on a region of the interface die 205 (e.g., at or near temperature sensor 215-a) being 100° Celsius when the clock tree meets a performance threshold at 20° Celsius (e.g., the clock tree is above the temperature threshold for meeting the performance threshold and the clock tree sensitivity may not be within an adequate range).

In some examples, the memory system controller may determine to write the data in a relatively colder region above the interface die 205 (e.g., compared to above the region where the temperature exceeds the temperature threshold). For example, the memory system controller may write the data to a region of a memory die 210 that is above a region of the interface die 205 having a temperature that does not exceed the temperature threshold. The area of the memory die 210 may correspond to one or more channels 220 that are not associated with a region of the interface die 205 having a temperature that exceeds the temperature threshold. For example, if the temperature of the region around the temperature sensor 215-a exceeds the temperature threshold, the memory system controller may write the data to the one or more memory dies 210 via the channels 220 near the temperature sensor 215-e (e.g., where the temperature does not exceed the temperature threshold).

In some examples, the memory system controller may transmit an indication (e.g., a recommendation), to the host system, indicating which memory die 210 (and what region of the memory die) to write the data to based on the temperature data. For example, the memory system controller may indicate to write data to portions of one or more memory dies 210 above regions of the interface die 205 that do not exceed the temperature threshold. Additionally, or alternatively, the memory system controller may indicate to write data to memory dies 210 associated with channels 220 with temperatures that do not exceed the temperature threshold.

The memory system controller may determine to cool the detected hot spots of the interface die 205, the at least one memory die 210, or both. In some examples, the memory system controller may activate or deactivate different parts of the interface die 205. For example, the memory system controller may disable one or more voltage rails in the interface die 205 or in one or more of the memory dies 210. Additionally, or alternatively, the memory system controller may split up voltage rails coupled with different temperature sensors 215. For example, the memory system controller may decouple one or more voltage rails coupled with the temperature sensor 215-a and the temperature sensor 215-b based on a hotspot at the temperature sensor 215-b. In some cases, the memory system controller may activate or deactivate one or more local controllers (e.g., a local controller 150), or one or more memory arrays (e.g., a memory array 155) corresponding to the one or more memory dies 210. In some examples, the memory system controller may deactivate one or more channels 220 located in a hotspot of the interface die 205.

Additionally, or alternatively, the memory system controller may throttle one or more channels 220. For example, the memory system controller may decrease an operating frequency (e.g., throttle) of one or more channels 220 corresponding to a hotspot of the interface die 205. In some examples, the memory system controller may transmit an indication to the host system direct traffic (e.g., write commands or read commands) to other channels 220 (e.g., channels 220 not associated with a hotspot). In some examples, the memory system controller may transmit the indication to an end-user.

In some cases, the memory system controller may initiate a shutdown of the interface die 205 based on a temperature of the interface die 205 or the at least one memory die 210 exceeding the temperature threshold (e.g., to cool a detected hotspot). For example, the memory system controller may transition the interface die 205, the one or more memory dies 210, or both from a first power state to a second power state, where the second power state is less than the first power state. Accordingly, the architecture 200 may support distributed temperature sensors, which may enable a memory system controller to improve the overall performance of a memory system and increase its life-cycle by reducing temperatures that exceed a temperature threshold would have otherwise degraded aspects of the memory system.

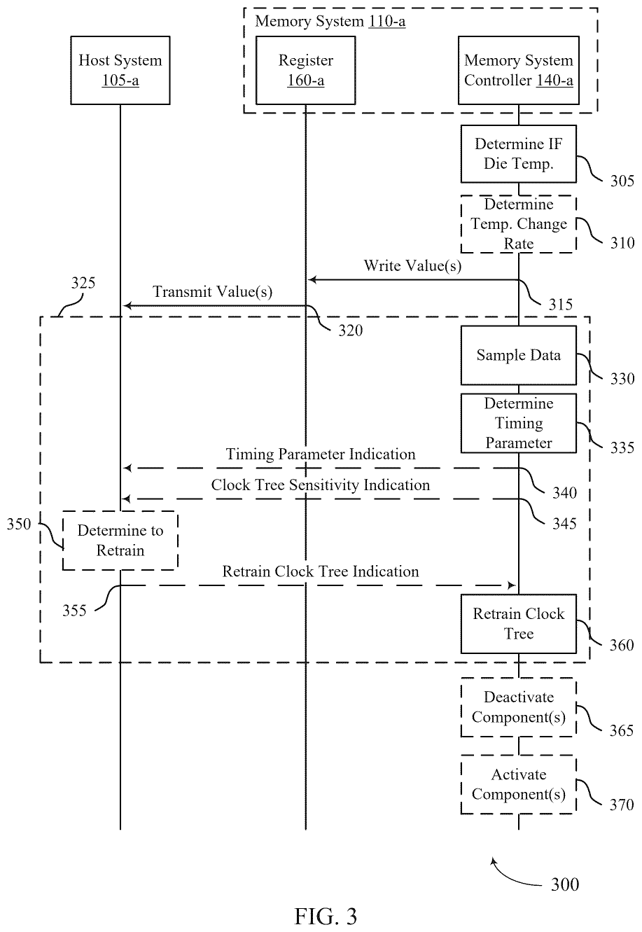

FIG. 3 shows an example of a process flow 300 that supports distributed temperature sensors in a die of a memory device in accordance with examples as disclosed herein. The process flow 300 may be implemented by aspects of the system 100 and the architecture 200 as described with reference to FIGS. 1 and 2, respectively. For example, the process flow 300 may be implemented by a host system 105-a and a memory system 110-a which may be an example of the host system 105 and the memory system 110 as described with reference to FIG. 1. The memory system 110-a may include a memory system controller 140-a and a register 160-a, which may be examples of the memory system controller 140 and the register 160 described with reference to FIGS. 1 and 2. As described further with reference to FIG. 2, the memory system 110-b may include an interface die, multiple temperature sensors distributed across multiple regions of the interface die, and one or more memory dies stacked above the interface die that each include a respective temperature sensor.

In the following description of the process flow 300, the operations may be performed in a different order than the order shown, or other operations may be added or removed from the process flow 300. For example, some operations may also be left out of the process flow 300, may be performed in different orders or at different times, or other operations may be added to the process flow 300. Although a memory system (e.g., the memory system 110) may perform the operations of the process flow 300, some aspects of some operations may also be performed by one or more other memory systems, memory devices, host devices, controllers or other electronic devices (e.g., as described herein with respect to FIG. 1).

In some examples, the memory system controller 140-a may receive temperature data from multiple temperature sensors of an interface die of the memory system 110-a. In some examples, the temperature data may include temperature values (e.g., in degrees) sensed by the temperature sensors. Additionally, or alternatively, the temperature data may include a rate of change of the temperature values (e.g., a slope of the temperature over time). In some examples, the memory system controller 140-a may receive the temperature data periodically or in response to requesting the temperature data from a respective temperature sensor. In other examples, the memory system controller 140-a may receive the temperature data in response to a temperature value exceeding a temperature threshold (e.g., a temperature sensor may report based on sensing a hotspot). The memory system controller 140-a may receive an indication of the position of the temperature sensor in addition to the temperature data sensed by the temperature sensor (e.g., left, center right; top, middle, bottom; center, edge; etc.)

At 305, the memory system controller 140-a may determine that a first temperature of an interface die (e.g., the interface die 205) satisfies a temperature threshold via one or more of the multiple temperature sensors. For example, the multiple temperature sensors may be distributed across multiple regions of the interface die, such as the temperature sensors 215-a through 215-e described with reference to FIG. 2. In some examples, the first temperature may correspond to at least one region of the multiple regions of the interface die, and the temperature threshold may correspond to a maximum temperature of the interface die (e.g., or a region of the interface die) during a duration of time.

At 310, the memory system controller 140-a may determine that a rate of change of the first temperature satisfies a temperature change rate threshold. For example, the first temperature may increase from a first temperature value to a second temperature value in a relatively short duration. In some cases, the memory system controller 140-a may estimate (e.g., determine) that the first temperature exceeded the temperature threshold based on the rate of change of the first temperature. In some examples, the rate of change of the first temperature may be associated with an unexpected change in temperature. For example, nominal operations at the memory system 110-a may correspond to a first temperature pattern (e.g., an increase in write commands to the memory system 110-a may proportionally increase the temperature). In response to the first temperature deviating from the first temperature pattern over a duration (e.g., changing unexpectedly), the memory system controller 140-a may determine that the rate of change of the first temperature satisfies the temperature change rate threshold.

Additionally, or alternatively, the memory system controller 140-a may determine that a second temperature of the memory system 110-a is different than the first temperature by a threshold difference. The second temperature may correspond to at least a second region of the interface die. In some examples, a difference in temperature at the temperature sensors distributed across the interface die may correspond to degradation of the hotter regions of the interface die. For example, regions of the interface die with temperatures a threshold temperature difference (e.g., a threshold difference hotter) than other regions of the interface die may degrade relatively faster than regions of the interface die with temperatures that do not exceed the threshold temperature difference.

At 315, the memory system controller 140-a may write one or more values associated with the first temperature of the memory system to the register 160-a. The memory system controller 140-a may write the one or more values to increase storage efficiency (e.g., optimize) of temperature information for read out by the host system 105-a. In some examples, the one or more values may correspond to the first temperature based on the first temperature satisfying the temperature threshold. In other examples, the one or more values may correspond to the difference between the first temperature and the second temperature (e.g., based on the second temperature being different than the first temperature by the threshold difference). Additionally, or alternatively, the memory system controller 140-a may write a value corresponding to multiple temperatures being within a same range. For example, the memory system controller 140-a may determine, via the multiple temperature sensors, that multiple temperatures of the memory system are each above a respective lower temperature threshold (e.g., a lower bound) and below a respective upper temperature threshold (e.g., an upper bound). The memory system controller 140-a may write a single value corresponding to the multiple temperatures in response to the multiple temperatures satisfying the temperature range threshold.

At 320, the memory system controller 140-a may transmit the one or more values to the host system 105-a (e.g., the memory system controller 140-a may perform health monitoring reporting). For example, the memory system controller 140-a may transmit, to the host system 105-a (e.g., a controller of the host system 105-a), an indication that the first temperature of the at least one region satisfies the temperature threshold. Additionally, or alternatively, the memory system controller 140-a may transmit the indication based on the rate of change of the first temperature satisfying the temperature change rate threshold, the temperature difference threshold, or both.

The memory system controller 140-a may transmit the indication based on writing the one or more values to the register 160-a. In some examples, the one or more values may further indicate the location of the temperature data. For example, the memory system controller 140-a may determine a second temperature of the memory system 110-a satisfies the temperature threshold. The second temperature may correspond to a second region of the interface die. The memory system controller 140-a may indicate, via the one or more values, the at least one region corresponding to the first temperature and the second region corresponding to the second temperature. That is, the memory system controller 140-a may transmit temperature information according to a location where the temperature information was sensed (e.g., the left side of the interface die, the middle of the interface die, the right side of the interface die, and the like).

In some examples, the host system 105-a may receive the one or more values based on reading the register 160-a. In some cases, the host system 105-a may read the register 160-a periodically (e.g., at a predefined or set cadence). In other cases, the host system 105-a may read the register 160-a before or after transmitting an access command, such as a read or write command, to the memory system 110-a. In some examples, as described further with reference to FIG. 2, the temperature of the interface die may affect a propagation delay (e.g., a timing parameter) of a clock signal of the memory system 110-a. Temperatures that satisfy (e.g., exceed) the temperature threshold may result in longer durations to complete write commands. Accordingly, the host system 105-a and the memory system 110-a may perform an operation at 325 to adjust the clock signal of the memory system 110-a based on the temperature of one or more regions of the interface die satisfying the temperature threshold.

At 330, the memory system controller 140-a may sample first data using a timing parameter (e.g., a propagation delay) of a clock signal associated with a signal path (e.g., the clock tree) that may propagate through the multiple regions of the interface die. In some examples, the memory system controller 140-a may sample the first data based on determining that the first temperature of the interface die satisfies the temperature threshold. In other examples, the memory system controller 140-a may sample the first data based on writing the one or more values to the register 160-a (e.g., based on one or more temperatures satisfying the temperature change rate threshold and/or the temperature difference threshold). The first data may be associated with a first memory die of the memory system 110-a (e.g., the memory die 210-a). For example, the memory system controller 140-a may receive a write command including the first data and indication of the first memory die (e.g., where the first data is to be stored).

At 335, the memory system controller 140-a may determine that the timing parameter (e.g., the propagation delay) satisfies a timing threshold based on sampling the first data. For example, the memory system controller 140-a may determine that the propagation delay of the clock signal exceeds a timing threshold (e.g., the clock signal propagation delay may be increased based on the temperature of a region of the interface die).

At 340, the memory system controller 140-a may output an indication of the timing parameter to the host system 105-a. In some examples, the memory system controller 140-a may output the indication via the register 160-a. For example, the memory system controller 140-a may write one or more values corresponding to the timing parameter to the register 160-a, and the host system 105-a may read the one or more values in the register 160-a.

In some examples, at 345, the memory system controller 140-a may output a clock sensitivity value based on a nominal temperature of the memory system. For example, as described further with reference to FIG. 2, the clock sensitivity value may indicate how sensitive the propagation delay of the clock signal is to temperature (e.g., the clock sensitivity value may be 1 ps per degree). In some examples, the memory system controller 140-a may output the clock sensitivity value via the register 160-a.

At 350, the host system 105-a may determine whether to adjust one or more parameters associated with the clock signal (e.g., the host system 105-a may determine whether to retrain the clock signal). In some examples, the determining may be based on a system cooling capability. For example, the host system 105-a may receive the clock sensitivity value and determine not adjust the one or more parameters based on the system cooling capability satisfying a cooling threshold (e.g., the host system 105-a may be able to cool the interface die such that the temperature does not satisfy the threshold). In other examples, the host system 105-a may determine to adjust the one or more parameters based on the system cooling capability not satisfying the cooling threshold. In such examples, at 355, the memory system controller 140-a may receive an indication to adjust the one or more parameters (e.g., to retrain the clock).

At 360, the memory system controller 140-a may adjust one or more parameters associated with the clock signal in response to determining that the timing parameter satisfies the timing threshold (e.g., and/or in response to receiving the indication to adjust the one or more parameters from the host system 105-a). In some examples, adjusting the one or more parameters may include adjusting a data sampling rate of the memory system 110-a based on the timing parameter. For example, the memory system controller 140-a may adjust the length of the first data to match the length of the clock signal (e.g., increase the length of the data to compensate for the increased length of the clock signal). Additionally, or alternatively, the memory system controller 140-a may determine to write the first data to a second memory die (e.g., associated with a relatively colder region than the first memory die). For example, a clock signal of the second memory die may be unaffected by the first temperature (e.g., based on the temperature of the second memory die not satisfying the temperature threshold).

In some examples, writing to a different memory die or adjusting the sampling rate may enable the memory system controller 140-a to write the first data, but the first temperature may remain above the temperature threshold (e.g., writing to a different die or adjusting the sampling rate may not cool the hotspot of the first memory die or the interface die). Accordingly, the memory system controller 140-a may adjust one or more parameters to reduce the first temperature below the temperature threshold.

At 365, the memory system controller 140-a may deactivate one or more components associated with the at least one region with the first temperature (e.g., that satisfies the temperature threshold). For example, the memory system controller 140-a may deactivate a first set of voltage rails positioned in, relatively close to (e.g., such that the temperature of the first set of voltage rails is equal to the first temperature), or otherwise associated with, the at least one region. In some examples, the memory system controller 140-a may deactivate one or more local controllers or memory arrays associated with the at least one region. Additionally, or alternatively, the memory system controller 140-a may deactivate one or more channels positioned in, or relatively close to, the at least one region, as described further with reference to FIG. 2.

At 370, the memory system controller 140-a may activate one or more components associated with at least a second region with a second temperature (e.g., a region of the interface die whose temperature does not satisfy the temperature threshold). For example, the memory system controller 140-a may activate a second set of voltage rails positioned in, relatively close to, or otherwise associated with, the second region. In some examples, activating the second set of voltage rails and deactivating the first set of voltage rails may reduce the first temperature (e.g., active voltage rails may increase the temperature of their respective region).

In some examples, the memory system controller 140-a may activate one or more local controllers or memory arrays associated with the at second region to reduce the first temperature. Additionally, or alternatively, the memory system controller 140-a may activate one or more channels positioned in, or relatively close to, the second region, as described further with reference to FIG. 2. Accordingly, the memory system 110-a may support distributed temperature sensors, which may enable a memory system controller to improve the overall performance of a memory system and increase its life-cycle by reducing temperatures that exceed a temperature threshold would have otherwise degraded aspects of the memory system.

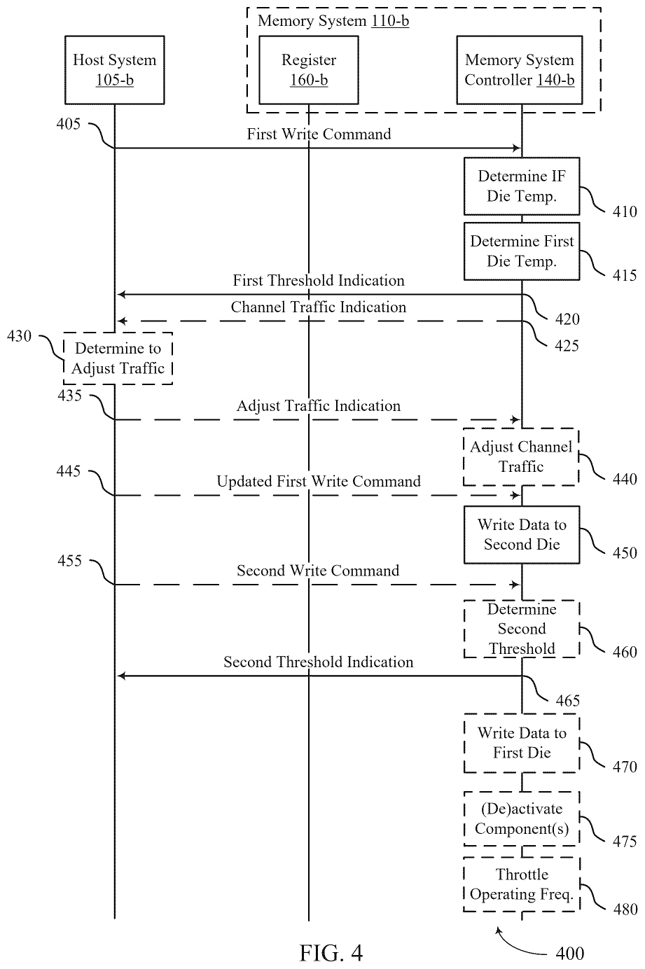

FIG. 4 shows an example of a process flow 400 that supports distributed temperature sensors in a die of a memory device in accordance with examples as disclosed herein. The process flow 400 may be implemented by aspects of the system 100 and the architecture 200 as described with reference to FIGS. 1 and 2, respectively. For example, the process flow 400 may be implemented by a host system 105-b and a memory system 110-b which may be an example of the host system 105 and the memory system 110 as described with reference to FIG. 1. The memory system 110-b may include a memory system controller 140-b and a register 160-b, which may be examples of the memory system controller 140 and the register 160 described with reference to FIGS. 1 and 2. As described further with reference to FIG. 2, the memory system 110-b may include an interface die, multiple temperature sensors distributed across multiple regions of the interface die, and one or more memory dies stacked above the interface die. In some examples, each of the one or more memory dies may include a respective temperature sensor. The memory system controller 140-b may receive temperature data from each of the temperature sensors in the interface die and the one or more memory dies.

In the following description of the process flow 400, the operations may be performed in a different order than the order shown, or other operations may be added or removed from the process flow 400. For example, some operations may also be left out of the process flow 400, may be performed in different orders or at different times, or other operations may be added to the process flow 400. Although a memory system (e.g., the memory system 110) may perform the operations of the process flow 400, some aspects of some operations may also be performed by one or more other memory systems, memory devices, host devices, controllers or other electronic devices (e.g., as described herein with respect to FIG. 1). The operations of the process flow 400 may be an extension of the process flow 300. For example, it may be understood that the process flow 400 may include any of the operations described with reference to the process flow 300 (e.g., and vice versa). That is, the different operations described in the process flow 400 and the process flow 300 may not signify any distinct separation or exclusion of the operations described herein.

At 405, the memory system controller 140-b may receive a first write command for writing first data to a first memory die of the memory system 110-b. For example, the first write command may include the first data and an indication for the memory system 110-b to write the first data to the first memory die.

At 410, the memory system controller 140-b may determine, via the multiple temperature sensors of the interface die, whether a first temperature of satisfies a temperature threshold (e.g., the temperature threshold as described with reference to FIGS. 2 and 3). In some examples, the first temperature may correspond to at least one region of the interface die. If the first temperature satisfies the temperature threshold, the memory system controller 140-b may transmit an indication (e.g., via the register 160-b) to the host system 105-b, and adjust one or more parameters to reduce the first temperature, as described with reference to FIG. 3 (e.g., operations 305-320 and operations 365-370).

Additionally, or alternatively, the memory system controller 140-b may adjust one or more parameters associated with a clock signal of the memory system 110-b, as discussed further with reference to FIG. 3 (e.g., operations 330-360). If the first temperature does not satisfy the temperature threshold, the memory system controller 140-b may not adjust the one or more parameters (e.g., the temperature of the region of the interface die may be within nominal operating temperatures). In some examples, the memory system controller 140-b may transmit an indication to the host system 105-b that the first temperature does not satisfy the temperature threshold.

At 415, the memory system controller 140-b may determine, via a second temperature sensor of the first memory die, whether the second temperature satisfies the temperature threshold. The second temperature may correspond to the first memory die. If the second temperature does not satisfy the temperature threshold, the memory system controller 140-b may not adjust one or more parameters (e.g., the temperature of the first memory die may be within nominal operating temperatures). In some examples, the memory system controller 140-b may transmit an indication to the host system 105-b that the second temperature does not satisfy the temperature threshold.

At 420, the memory system controller 140-b may transmit, to the host system 105-a (e.g., a controller of the memory system 110-b), an indication that the second temperature satisfies the temperature threshold based on determining that the second temperature satisfies the temperature threshold.

In some examples, at 425, the memory system controller 140-b may transmit an indication (e.g., via the register 160-b) to reduce traffic associated with one or more channels of the memory system 110-b based on the first temperature satisfying the temperature threshold. For example, the traffic may correspond to a quantity of access commands the memory system controller 140-b receives in a duration. In some examples, reducing the quantity of access commands received may reduce the first temperature. For example, an access command may correspond to a current through one or more components of the interface die, which may increase the temperature of a region of the interface die.

At 430, the host system 105-b may determine whether to adjust the traffic in response to the indication to reduce traffic. In some examples, the host system 105-b may determine not to adjust the traffic. For example, the host system 105-b may not adjust the traffic based on a cooling capability as described with reference to FIG. 3. In other examples, at 435, the host system 105-b may transmit an indication to adjust (e.g., reduce) the traffic. The indication to adjust the traffic may include an indication to reduce the traffic for one or more channels of the at least one region of the interface die and to proportionally increase the traffic for one or more other channels of at least a second region of the interface die. For example, if the first region is associated with the approximate center of the interface die, the indication to adjust the traffic may indicate the memory system controller 140-b to avoid traffic on the center channels (e.g., reroute the traffic to outer channels). Additionally, or alternatively, the indication to adjust the traffic may include an indication that the host system 105-b may transmit fewer access commands to the first memory die (e.g., until the first temperature is reduced below the temperature threshold).

At 440, the memory system controller 140-b may adjust the traffic associated with the one or more channels of the memory system 110-b. In some examples, the memory system controller 140-b may adjust the traffic based on the first temperature satisfying the temperature threshold. In other examples, the memory system controller 140-b may adjust the traffic based on receiving the indication to adjust the traffic from the host system 105-b. The memory system controller 140-b may adjust the traffic by reducing the traffic corresponding to one or more channels of the at least one region of the interface die. Additionally, or alternatively, the memory system controller 140-b may increase the traffic (e.g., proportionate to the reduced traffic) corresponding to one or more other channels of at least a second region of the interface die.

In some examples, at 445, the memory system controller 140-b may receive an updated write command for writing the first data to a second memory die of the memory system 110-b. For example, the memory system controller 140-b may receive the updated write command based on transmitting the indication that the second temperature of the first memory die satisfies the temperature threshold.

At 450, the memory system controller 140-b may write the first data to the second memory die of the memory system. For example, the memory system controller 140-b may refrain from writing the first data to the first memory die based on transmitting the indication that the second temperature satisfies the temperature threshold, and the memory system controller 140-b may write the first data to the second memory die. Additionally, or alternatively, the memory system controller 140-b may write the first data to the second memory die based on receiving the updated write command (e.g., the host system 105-b may trigger writing to another DRAM die instead).

At 455, the memory system controller 140-b may receive a second write command for writing second data to the first memory die of the memory system 110-b. For example, the second write command may include the second data and an indication for the memory system 110-b to write the second data to the first memory die.

At 460, the memory system controller 140-b may determine, via the multiple temperature sensors, whether a third temperature of the memory system 110-b or a fourth temperature of the memory system 110-b satisfies the temperature threshold. The third temperature may correspond to at least one region of the interface die and the fourth temperature may correspond to the first memory die. If the third temperature of the memory system 110-b satisfies the threshold temperature, the memory system controller 140-b may transmit an indication (e.g., via the register 160-b) to the host system 105-b, and adjust one or more parameters to reduce the first temperature, as described with reference to FIG. 3 (e.g., operations 305-320 and operations 365 and 370).

Additionally, or alternatively, the memory system controller 140-b may adjust one or more parameters associated with a clock signal of the memory system 110-b, as discussed further with reference to FIG. 3 (e.g., operations 330-360). If the third temperature does not satisfy the temperature threshold, the memory system controller 140-b may not adjust the one or more parameters (e.g., the temperature of the region of the interface die may be within nominal operating temperatures). In some examples, the memory system controller 140-b may transmit an indication to the host system 105-b that the third temperature does not satisfy the temperature threshold.

If the fourth temperature does not satisfy the temperature threshold, the memory system controller 140-b may not adjust one or more parameters (e.g., the temperature of the first memory die is within nominal operating temperatures). In some examples, the memory system controller 140-b may transmit an indication to the host system 105-b that the fourth temperature does not satisfy the temperature threshold.

At 465, the memory system controller 140-b may transmit, to the host system 105-a an indication that the fourth temperature satisfies the temperature threshold based on determining that the second temperature satisfies the temperature threshold.

At 470, the memory system controller 140-b may write the second data to the first memory die at a second frequency that is less than a first frequency used to write the first data to the second memory die. For example, the memory system controller 140-b may limit writing data to the first memory die based on the temperature of the first memory die satisfying the temperature threshold. In some examples, writing data to the first memory die less frequently compared to writing data to the second memory die may reduce the temperature of the first memory die (e.g., the fourth temperature) below the temperature threshold.

At 475, the memory system controller 140-b may activate or deactivate one or more components of the interface die, the one or more memory dies, or both, as described with reference to operations 365 and 370 in FIG. 3. For example, the memory system controller 140-b may disable one or more components of the memory system 110-b based on determining that the first temperature (e.g., or the third temperature), the second temperature (e.g., or the fourth temperature), or a combination thereof, satisfy the temperature threshold. The one or more components may include one or more channels. For example, the memory system controller 140-b may disable one or more channels coupled with the interface die and the first memory die based on determining the first temperature, the second temperature, or both, satisfy the temperature threshold.

At 480, the memory system controller 140-b may reduce an operating frequency (e.g., throttle downward) of one or more channels coupled with the interface die and the first memory die based on determining the first temperature, the second temperature, or both, satisfy the temperature threshold. In some examples, reducing the operating frequency of a respective die may reduce the temperature of the respective die. Accordingly, the memory system 110-a may support distributed temperature sensors, which may enable a memory system controller to improve the overall performance of a memory system and increase its life-cycle by reducing temperatures that exceed a temperature threshold would have otherwise degraded aspects of the memory system.

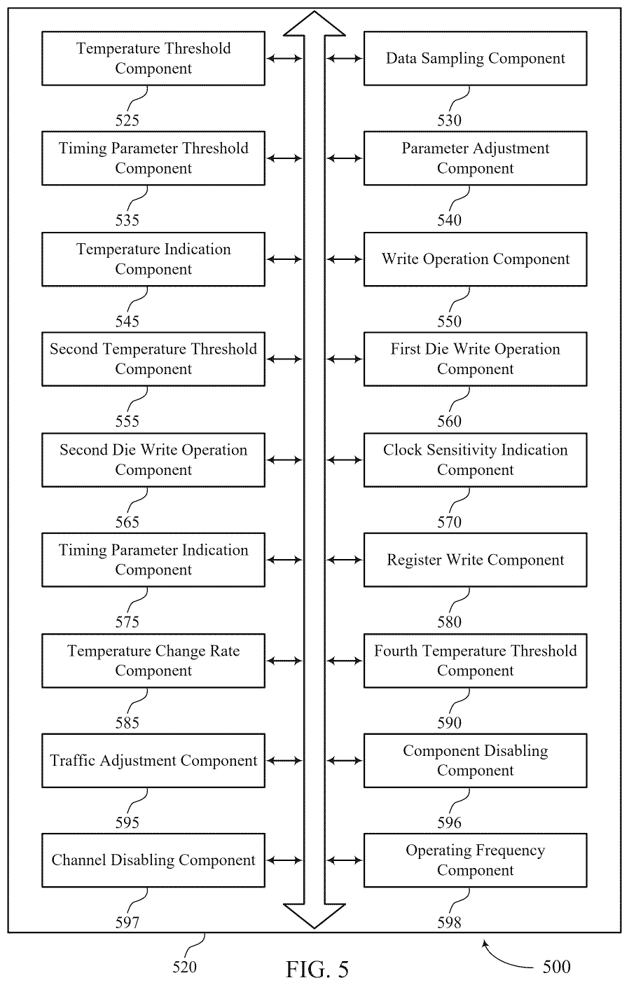

FIG. 5 shows a block diagram 500 of a memory system 520 that supports distributed temperature sensors in a die of a memory device in accordance with examples as disclosed herein. The memory system 520 may be an example of aspects of a memory system as described with reference to FIGS. 1 through 4. The memory system 520, or various components thereof, may be an example of means for performing various aspects of distributed temperature sensors in a die of a memory device as described herein. For example, the memory system 520 may include a temperature threshold component 525, a data sampling component 530, a timing parameter threshold component 535, a parameter adjustment component 540, a temperature indication component 545, a write operation component 550, a second temperature threshold component 555, a first die write operation component 560, a second die write operation component 565, a clock sensitivity indication component 570, a timing parameter indication component 575, a register write component 580, a temperature change rate component 585, a fourth temperature threshold component 590, a traffic adjustment component 595, a component disabling component 596, a channel disabling component 597, an operating frequency component 598, or any combination thereof. Each of these components, or components of subcomponents thereof (e.g., one or more processors, one or more memories), may communicate, directly or indirectly, with one another (e.g., via one or more buses).

The temperature threshold component 525 may be configured as or otherwise support a means for determining, via a plurality of temperature sensors of an interface die of the memory system, that a first temperature of the interface die satisfies a temperature threshold, where the plurality of temperature sensors are distributed across a plurality of regions of the interface die, and where the first temperature corresponds to at least one region of the plurality of regions. The data sampling component 530 may be configured as or otherwise support a means for sampling first data using a timing parameter of a clock signal associated with a signal path associated with the plurality of regions based at least in part on determining that the first temperature of the interface die satisfies the temperature threshold, where the first data is associated with a first memory die of the memory system. The timing parameter threshold component 535 may be configured as or otherwise support a means for determining that the timing parameter satisfies a timing threshold based at least in part on sampling the first data using the timing parameter. The parameter adjustment component 540 may be configured as or otherwise support a means for adjusting one or more parameters associated with the clock signal based at least in part on determining that the timing parameter satisfies the timing threshold.

In some examples, the clock sensitivity indication component 570 may be configured as or otherwise support a means for outputting an indication of a clock sensitivity value based at least in part on a nominal temperature of the memory system, where adjusting the one or more parameters is based at least in part on outputting the indication of the clock sensitivity value.

In some examples, the timing parameter indication component 575 may be configured as or otherwise support a means for outputting an indication of the timing parameter, where adjusting the one or more parameters associated with the clock signal is based at least in part on outputting the indication of the timing parameter.

In some examples, to support adjusting the one or more parameters associated with the clock signal, the parameter adjustment component 540 may be configured as or otherwise support a means for adjusting a data sampling rate of the memory system based at least in part on the timing parameter.

In some examples, the temperature threshold component 525 may be configured as or otherwise support a means for determining, via a plurality of temperature sensors of an interface die of the memory system, that a first temperature of the memory system satisfies a temperature threshold, where the plurality of temperature sensors are distributed across a plurality of regions of the interface die, and where the first temperature corresponds to at least one region of the plurality of regions. The temperature indication component 545 may be configured as or otherwise support a means for transmitting, to a controller of the memory system, an indication that the first temperature of the at least one region satisfies the temperature threshold based at least in part on determining that the first temperature satisfies the temperature threshold. In some examples, the parameter adjustment component 540 may be configured as or otherwise support a means for adjusting one or more parameters associated with the plurality of regions to reduce the first temperature below the temperature threshold based at least in part on outputting the indication.

In some examples, the register write component 580 may be configured as or otherwise support a means for writing, to a register of the memory system, one or more values associated with the first temperature of the memory system, where transmitting the indication is based at least in part on writing the one or more values to the register.

In some examples, to support writing the one or more values to the register of the memory system, the register write component 580 may be configured as or otherwise support a means for determining, via the plurality of temperature sensors, that a plurality of second temperatures of the memory system are each above a respective lower temperature threshold and below a respective upper temperature threshold. In some examples, to support writing the one or more values to the register of the memory system, the register write component 580 may be configured as or otherwise support a means for writing, to the register of the memory system, a single value corresponding to the plurality of second temperatures based on the plurality of second temperatures being above the respective lower temperature threshold and below the respective upper temperature threshold.

In some examples, to support writing the one or more values to the register of the memory system, the register write component 580 may be configured as or otherwise support a means for determining, via the plurality of temperature sensors, that a second temperature of the memory system is different than the first temperature by a threshold difference, where the second temperature corresponds to at least a second region of the interface die. In some examples, to support writing the one or more values to the register of the memory system, the register write component 580 may be configured as or otherwise support a means for writing, to the register of the memory system, a value indicating a difference between the first temperature and the second temperature.

In some examples, the second temperature threshold component 555 may be configured as or otherwise support a means for determining, via the plurality of temperature sensors, that a second temperature of the memory system satisfies the temperature threshold, where the second temperature corresponds to a second region of the plurality of regions, and where the indication further indicates the at least one region corresponds to the first temperature and the second region corresponding to the second temperature.

In some examples, the temperature change rate component 585 may be configured as or otherwise support a means for determining that a rate of change of the first temperature satisfies a temperature change rate threshold, where transmitting the indication is based at least in part on the rate of change of the first temperature satisfying the temperature change rate threshold.

In some examples, to support adjusting the one or more parameters associated with the plurality of regions, the parameter adjustment component 540 may be configured as or otherwise support a means for deactivating a first set of voltage rails associated the at least one region. In some examples, to support adjusting the one or more parameters associated with the plurality of regions, the parameter adjustment component 540 may be configured as or otherwise support a means for activating a second set of voltage rails associated with at least a second region, where deactivating the first set of voltage rails and activating the second set of voltage rails is associated with reducing the first temperature. In some examples, the temperature threshold includes a maximum temperature of the interface die during a duration of time.

The write operation component 550 may be configured as or otherwise support a means for receiving a write command for writing first data to a first memory die of the memory system. In some examples, the temperature threshold component 525 may be configured as or otherwise support a means for determining, via a first plurality of temperature sensors of an interface die of the memory system and a second temperature sensor of a first memory die of the memory system, whether a first temperature or a second temperature of the memory system satisfy a temperature threshold, where the first plurality of temperature sensors are distributed across a plurality of regions of the interface die, and where the first temperature corresponds to at least one region of the plurality of regions, and where the second temperature corresponds to the first memory die. The second temperature threshold component 555 may be configured as or otherwise support a means for transmitting, to a controller of the memory system, an indication that the second temperature satisfies the temperature threshold based at least in part on determining that the second temperature satisfies the temperature threshold. The first die write operation component 560 may be configured as or otherwise support a means for refraining from writing the first data to the first memory die based at least in part on transmitting the indication that the second temperature satisfies the temperature threshold. The second die write operation component 565 may be configured as or otherwise support a means for writing the first data to a second memory die of the memory system based at least in part on refraining from writing the first data to the first memory die.

In some examples, the second temperature threshold component 555 may be configured as or otherwise support a means for transmitting an indication that the second temperature satisfies the temperature threshold based at least in part on determining that the second temperature satisfies the temperature threshold. In some examples, the second die write operation component 565 may be configured as or otherwise support a means for receiving an updated write command for writing the first data to the second memory die of the memory system, where writing the first data to the second memory die of the memory system is based at least in part on receiving the updated write command.

In some examples, the write operation component 550 may be configured as or otherwise support a means for receiving a second write command for writing second data to the first memory die of the memory system. In some examples, the temperature threshold component 525 may be configured as or otherwise support a means for determining, via the first plurality of temperature sensors and the second temperature sensor, whether a third temperature or a fourth temperature of the memory system satisfy the temperature threshold, where the third temperature corresponds to at least one region of the plurality of regions, and where the fourth temperature corresponds to the first memory die. In some examples, the fourth temperature threshold component 590 may be configured as or otherwise support a means for transmitting, to the controller of the memory system, a second indication that the fourth temperature satisfies the temperature threshold based at least in part on determining that the fourth temperature satisfies the temperature threshold. In some examples, the first die write operation component 560 may be configured as or otherwise support a means for writing the second data to the first memory die at a second frequency that is less than a first frequency used to write the first data to the second memory die.

In some examples, the traffic adjustment component 595 may be configured as or otherwise support a means for adjusting, by the controller, traffic associated with one or more channels of the memory system based at least in part on determining that the first temperature satisfies the temperature threshold.

In some examples, the traffic adjustment component 595 may be configured as or otherwise support a means for transmitting, by the controller, an indication to reduce traffic associated with one or more channels of the memory system based at least in part on determining that the first temperature satisfies the temperature threshold.

In some examples, the component disabling component 596 may be configured as or otherwise support a means for disabling one or more components of the memory system based at least in part on determining that the first temperature, the second temperature, or both satisfy the temperature threshold.

In some examples, the channel disabling component 597 may be configured as or otherwise support a means for disabling one or more channels coupled with the interface die and the first memory die of the memory system based at least in part on determining that the first temperature, the second temperature, or both satisfy the temperature threshold.

In some examples, the operating frequency component 598 may be configured as or otherwise support a means for reducing an operating frequency of one or more channels coupled with the interface die and the first memory die of the memory system based at least in part on determining that the first temperature, the second temperature, or both satisfy the temperature threshold.

In some examples, the described functionality of the memory system 520, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 520, or various components thereof, may be implemented at least in part by instructions (e.g., stored in memory, non-transitory computer-readable medium) executable by such at least one processor.

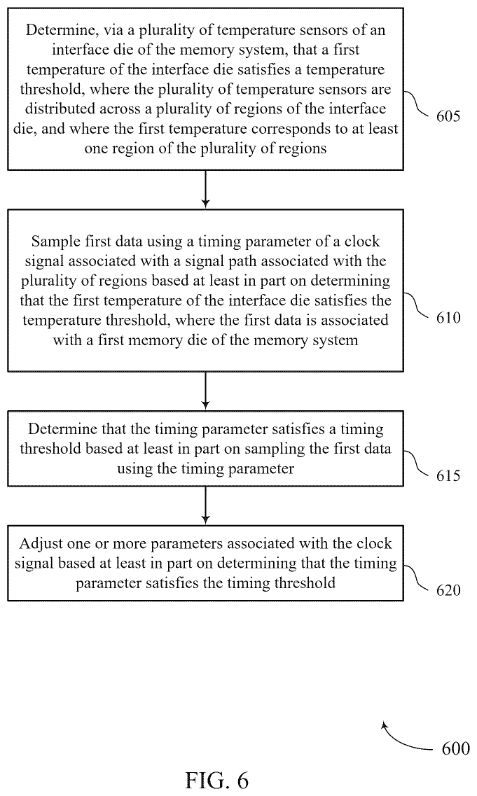

FIG. 6 shows a flowchart illustrating a method 600 that supports distributed temperature sensors in a die of a memory device in accordance with examples as disclosed herein. The operations of method 600 may be implemented by a memory system or its components as described herein. For example, the operations of method 600 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 605, the method may include determining, via a plurality of temperature sensors of an interface die of the memory system, that a first temperature of the interface die satisfies a temperature threshold, where the plurality of temperature sensors are distributed across a plurality of regions of the interface die, and where the first temperature corresponds to at least one region of the plurality of regions. In some examples, aspects of the operations of 605 may be performed by a temperature threshold component 525 as described with reference to FIG. 5.

At 610, the method may include sampling first data using a timing parameter of a clock signal associated with a signal path associated with the plurality of regions based at least in part on determining that the first temperature of the interface die satisfies the temperature threshold, where the first data is associated with a first memory die of the memory system. In some examples, aspects of the operations of 610 may be performed by a data sampling component 530 as described with reference to FIG. 5.

At 615, the method may include determining that the timing parameter satisfies a timing threshold based at least in part on sampling the first data using the timing parameter. In some examples, aspects of the operations of 615 may be performed by a timing parameter threshold component 535 as described with reference to FIG. 5.

At 620, the method may include adjusting one or more parameters associated with the clock signal based at least in part on determining that the timing parameter satisfies the timing threshold. In some examples, aspects of the operations of 620 may be performed by a parameter adjustment component 540 as described with reference to FIG. 5.

In some examples, an apparatus as described herein may perform a method or methods, such as the method 600. The apparatus may include features, circuitry, logic, means, or instructions (e.g., a non-transitory computer-readable medium storing instructions executable by a processor), or any combination thereof for performing the following aspects in accordance with examples as disclosed herein:
Aspect 1: A method, apparatus, or non-transitory computer-readable medium including operations, features, circuitry, logic, means, or instructions, or any combination thereof for determining, via a plurality of temperature sensors of an interface die of the memory system, that a first temperature of the interface die satisfies a temperature threshold, where the plurality of temperature sensors are distributed across a plurality of regions of the interface die, and where the first temperature corresponds to at least one region of the plurality of regions; sampling first data using a timing parameter of a clock signal associated with a signal path associated with the plurality of regions based at least in part on determining that the first temperature of the interface die satisfies the temperature threshold, where the first data is associated with a first memory die of the memory system; determining that the timing parameter satisfies a timing threshold based at least in part on sampling the first data using the timing parameter; and adjusting one or more parameters associated with the clock signal based at least in part on determining that the timing parameter satisfies the timing threshold.
Aspect 2: The method, apparatus, or non-transitory computer-readable medium of aspect 1, further including operations, features, circuitry, logic, means, or instructions, or any combination thereof for outputting an indication of a clock sensitivity value based at least in part on a nominal temperature of the memory system, where adjusting the one or more parameters is based at least in part on outputting the indication of the clock sensitivity value.
Aspect 3: The method, apparatus, or non-transitory computer-readable medium of any of aspects 1 through 2, further including operations, features, circuitry, logic, means, or instructions, or any combination thereof for outputting an indication of the timing parameter, where adjusting the one or more parameters associated with the clock signal is based at least in part on outputting the indication of the timing parameter.
Aspect 4: The method, apparatus, or non-transitory computer-readable medium of any of aspects 1 through 3, where adjusting the one or more parameters associated with the clock signal includes operations, features, circuitry, logic, means, or instructions, or any combination thereof for adjusting a data sampling rate of the memory system based at least in part on the timing parameter.

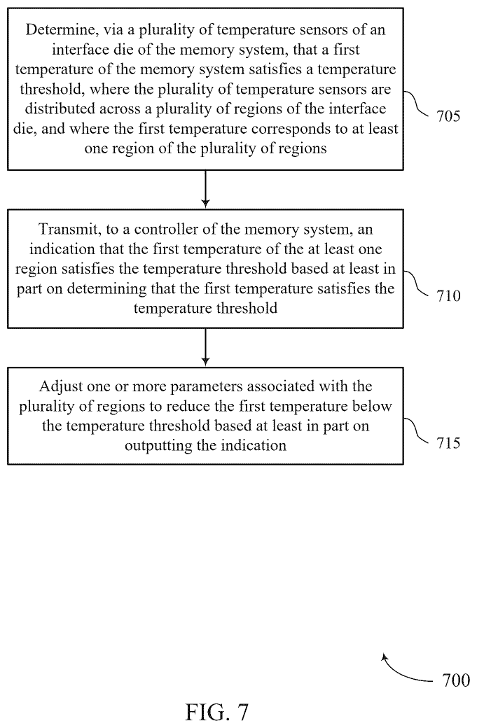

FIG. 7 shows a flowchart illustrating a method 700 that supports distributed temperature sensors in a die of a memory device in accordance with examples as disclosed herein. The operations of method 700 may be implemented by a memory system or its components as described herein. For example, the operations of method 700 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 705, the method may include determining, via a plurality of temperature sensors of an interface die of the memory system, that a first temperature of the memory system satisfies a temperature threshold, where the plurality of temperature sensors are distributed across a plurality of regions of the interface die, and where the first temperature corresponds to at least one region of the plurality of regions. In some examples, aspects of the operations of 705 may be performed by a temperature threshold component 525 as described with reference to FIG. 5.

At 710, the method may include transmitting, to a controller of the memory system, an indication that the first temperature of the at least one region satisfies the temperature threshold based at least in part on determining that the first temperature satisfies the temperature threshold. In some examples, aspects of the operations of 710 may be performed by a temperature indication component 545 as described with reference to FIG. 5.

At 715, the method may include adjusting one or more parameters associated with the plurality of regions to reduce the first temperature below the temperature threshold based at least in part on outputting the indication. In some examples, aspects of the operations of 715 may be performed by a parameter adjustment component 540 as described with reference to FIG. 5.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects in accordance with examples as disclosed herein:
Aspect 5: A method, apparatus, or non-transitory computer-readable medium including operations, features, circuitry, logic, means, or instructions, or any combination thereof for determining, via a plurality of temperature sensors of an interface die of the memory system, that a first temperature of the memory system satisfies a temperature threshold, where the plurality of temperature sensors are distributed across a plurality of regions of the interface die, and where the first temperature corresponds to at least one region of the plurality of regions; transmitting, to a controller of the memory system, an indication that the first temperature of the at least one region satisfies the temperature threshold based at least in part on determining that the first temperature satisfies the temperature threshold; and adjusting one or more parameters associated with the plurality of regions to reduce the first temperature below the temperature threshold based at least in part on outputting the indication.
Aspect 6: The method, apparatus, or non-transitory computer-readable medium of aspect 5, further including operations, features, circuitry, logic, means, or instructions, or any combination thereof for writing, to a register of the memory system, one or more values associated with the first temperature of the memory system, where transmitting the indication is based at least in part on writing the one or more values to the register.
Aspect 7: The method, apparatus, or non-transitory computer-readable medium of aspect 6, where writing the one or more values to the register of the memory system includes operations, features, circuitry, logic, means, or instructions, or any combination thereof for determining, via the plurality of temperature sensors, that a plurality of second temperatures of the memory system are each above a respective lower temperature threshold and below a respective upper temperature threshold and writing, to the register of the memory system, a single value corresponding to the plurality of second temperatures based on the plurality of second temperatures being above the respective lower temperature threshold and below the respective upper temperature threshold.
Aspect 8: The method, apparatus, or non-transitory computer-readable medium of any of aspects 6 through 7, where writing the one or more values to the register of the memory system includes operations, features, circuitry, logic, means, or instructions, or any combination thereof for determining, via the plurality of temperature sensors, that a second temperature of the memory system is different than the first temperature by a threshold difference, where the second temperature corresponds to at least a second region of the interface die and writing, to the register of the memory system, a value indicating a difference between the first temperature and the second temperature.
Aspect 9: The method, apparatus, or non-transitory computer-readable medium of any of aspects 5 through 8, further including operations, features, circuitry, logic, means, or instructions, or any combination thereof for determining, via the plurality of temperature sensors, that a second temperature of the memory system satisfies the temperature threshold, where the second temperature corresponds to a second region of the plurality of regions, and where the indication further indicates the at least one region corresponds to the first temperature and the second region corresponding to the second temperature.
Aspect 10: The method, apparatus, or non-transitory computer-readable medium of any of aspects 5 through 9, further including operations, features, circuitry, logic, means, or instructions, or any combination thereof for determining that a rate of change of the first temperature satisfies a temperature change rate threshold, where transmitting the indication is based at least in part on the rate of change of the first temperature satisfying the temperature change rate threshold.
Aspect 11: The method, apparatus, or non-transitory computer-readable medium of any of aspects 5 through 10, where adjusting the one or more parameters associated with the plurality of regions includes operations, features, circuitry, logic, means, or instructions, or any combination thereof for deactivating a first set of voltage rails associated the at least one region and activating a second set of voltage rails associated with at least a second region, where deactivating the first set of voltage rails and activating the second set of voltage rails is associated with reducing the first temperature.
Aspect 12: The method, apparatus, or non-transitory computer-readable medium of any of aspects 5 through 11, where the temperature threshold includes a maximum temperature of the interface die during a duration of time.

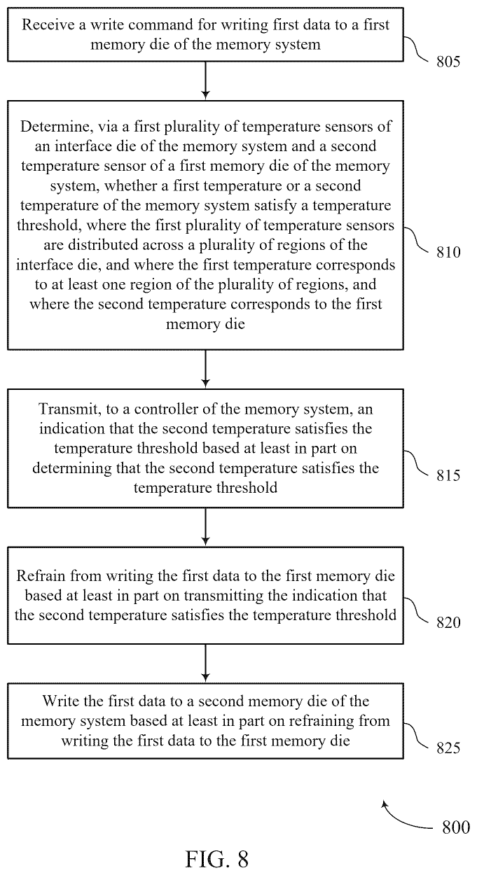

FIG. 8 shows a flowchart illustrating a method 800 that supports distributed temperature sensors in a die of a memory device in accordance with examples as disclosed herein. The operations of method 800 may be implemented by a memory system or its components as described herein. For example, the operations of method 800 may be performed by a memory system as described with reference to FIGS. 1 through 5. In some examples, a memory system may execute a set of instructions to control the functional elements of the device to perform the described functions. Additionally, or alternatively, the memory system may perform aspects of the described functions using special-purpose hardware.

At 805, the method may include receiving a write command for writing first data to a first memory die of the memory system. In some examples, aspects of the operations of 805 may be performed by a write operation component 550 as described with reference to FIG. 5.

At 810, the method may include determining, via a first plurality of temperature sensors of an interface die of the memory system and a second temperature sensor of a first memory die of the memory system, whether a first temperature or a second temperature of the memory system satisfy a temperature threshold, where the first plurality of temperature sensors are distributed across a plurality of regions of the interface die, and where the first temperature corresponds to at least one region of the plurality of regions, and where the second temperature corresponds to the first memory die. In some examples, aspects of the operations of 810 may be performed by a temperature threshold component 525 as described with reference to FIG. 5.

At 815, the method may include transmitting, to a controller of the memory system, an indication that the second temperature satisfies the temperature threshold based at least in part on determining that the second temperature satisfies the temperature threshold. In some examples, aspects of the operations of 815 may be performed by a second temperature threshold component 555 as described with reference to FIG. 5.

At 820, the method may include refraining from writing the first data to the first memory die based at least in part on transmitting the indication that the second temperature satisfies the temperature threshold. In some examples, aspects of the operations of 820 may be performed by a first die write operation component 560 as described with reference to FIG. 5.

At 825, the method may include writing the first data to a second memory die of the memory system based at least in part on refraining from writing the first data to the first memory die. In some examples, aspects of the operations of 825 may be performed by a second die write operation component 565 as described with reference to FIG. 5.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects in accordance with examples as disclosed herein:
Aspect 13: A method, apparatus, or non-transitory computer-readable medium including operations, features, circuitry, logic, means, or instructions, or any combination thereof for receiving a write command for writing first data to a first memory die of the memory system; determining, via a first plurality of temperature sensors of an interface die of the memory system and a second temperature sensor of a first memory die of the memory system, whether a first temperature or a second temperature of the memory system satisfy a temperature threshold, where the first plurality of temperature sensors are distributed across a plurality of regions of the interface die, and where the first temperature corresponds to at least one region of the plurality of regions, and where the second temperature corresponds to the first memory die; transmitting, to a controller of the memory system, an indication that the second temperature satisfies the temperature threshold based at least in part on determining that the second temperature satisfies the temperature threshold; refraining from writing the first data to the first memory die based at least in part on transmitting the indication that the second temperature satisfies the temperature threshold; and writing the first data to a second memory die of the memory system based at least in part on refraining from writing the first data to the first memory die.
Aspect 14: The method, apparatus, or non-transitory computer-readable medium of aspect 13, further including operations, features, circuitry, logic, means, or instructions, or any combination thereof for transmitting an indication that the second temperature satisfies the temperature threshold based at least in part on determining that the second temperature satisfies the temperature threshold and receiving an updated write command for writing the first data to the second memory die of the memory system, where writing the first data to the second memory die of the memory system is based at least in part on receiving the updated write command.
Aspect 15: The method, apparatus, or non-transitory computer-readable medium of any of aspects 13 through 14, further including operations, features, circuitry, logic, means, or instructions, or any combination thereof for receiving a second write command for writing second data to the first memory die of the memory system; determining, via the first plurality of temperature sensors and the second temperature sensor, whether a third temperature or a fourth temperature of the memory system satisfy the temperature threshold, where the third temperature corresponds to at least one region of the plurality of regions, and where the fourth temperature corresponds to the first memory die; transmitting, to the controller of the memory system, a second indication that the fourth temperature satisfies the temperature threshold based at least in part on determining that the fourth temperature satisfies the temperature threshold; and writing the second data to the first memory die at a second frequency that is less than a first frequency used to write the first data to the second memory die.
Aspect 16: The method, apparatus, or non-transitory computer-readable medium of any of aspects 13 through 15, further including operations, features, circuitry, logic, means, or instructions, or any combination thereof for adjusting, by the controller, traffic associated with one or more channels of the memory system based at least in part on determining that the first temperature satisfies the temperature threshold.
Aspect 17: The method, apparatus, or non-transitory computer-readable medium of any of aspects 13 through 16, further including operations, features, circuitry, logic, means, or instructions, or any combination thereof for transmitting, by the controller, an indication to reduce traffic associated with one or more channels of the memory system based at least in part on determining that the first temperature satisfies the temperature threshold.
Aspect 18: The method, apparatus, or non-transitory computer-readable medium of any of aspects 13 through 17, further including operations, features, circuitry, logic, means, or instructions, or any combination thereof for disabling one or more components of the memory system based at least in part on determining that the first temperature, the second temperature, or both satisfy the temperature threshold.
Aspect 19: The method, apparatus, or non-transitory computer-readable medium of any of aspects 13 through 18, further including operations, features, circuitry, logic, means, or instructions, or any combination thereof for disabling one or more channels coupled with the interface die and the first memory die of the memory system based at least in part on determining that the first temperature, the second temperature, or both satisfy the temperature threshold.
Aspect 20: The method, apparatus, or non-transitory computer-readable medium of any of aspects 13 through 19, further including operations, features, circuitry, logic, means, or instructions, or any combination thereof for reducing an operating frequency of one or more channels coupled with the interface die and the first memory die of the memory system based at least in part on determining that the first temperature, the second temperature, or both satisfy the temperature threshold.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:
Aspect 21: A memory system including: an interface die that includes a plurality of regions; a first plurality of temperature sensors distributed across the plurality of regions, where the first plurality of temperature sensors are configured to obtain a temperature of a respective region of the interface die; a first memory die coupled with the interface die; and a second temperature sensor located on the first memory die.
Aspect 22: The memory system of aspect 21, where: a first temperature sensor and a second temperature sensor of the first plurality of temperature sensors are aligned along a first boundary of the interface die; a third temperature sensor and a fourth temperature sensor of the first plurality of temperature sensors are aligned along a second boundary of the interface die; and the first temperature sensor, the third temperature sensor, and a fifth temperature sensor of the first plurality of temperature sensors are aligned colinearly.
Aspect 23: The memory system of aspect 22, further including: a plurality of data channels coupled with the interface die and the first memory die, where a first subset of the plurality of data channels is located between the first temperature sensor and the fifth temperature sensor, and a second subset of the plurality of data channels is located between the fifth temperature sensor and the third temperature sensor.
Aspect 24: The memory system of any of aspects 21 through 23, further including: a plurality of stacked memory dies above the first memory die, where each memory die of the plurality of stacked memory dies includes a respective temperature sensor.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an A SIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
determining, via a plurality of temperature sensors of an interface die of the memory system, that a first temperature of the interface die satisfies a temperature threshold, wherein the plurality of temperature sensors are distributed across a plurality of regions of the interface die, and wherein the first temperature corresponds to at least one region of the plurality of regions;
sampling first data using a timing parameter of a clock signal associated with a signal path associated with the plurality of regions based at least in part on determining that the first temperature of the interface die satisfies the temperature threshold, wherein the first data is associated with a first memory die of the memory system;
determining that the timing parameter satisfies a timing threshold based at least in part on sampling the first data using the timing parameter; and
adjusting one or more parameters associated with the clock signal based at least in part on determining that the timing parameter satisfies the timing threshold.

2. The method of claim 1, further comprising:
outputting an indication of a clock sensitivity value based at least in part on a nominal temperature of the memory system, wherein adjusting the one or more parameters is based at least in part on outputting the indication of the clock sensitivity value.

3. The method of claim 1, further comprising:
outputting an indication of the timing parameter, wherein adjusting the one or more parameters associated with the clock signal is based at least in part on outputting the indication of the timing parameter.

4. The method of claim 1, wherein adjusting the one or more parameters associated with the clock signal comprises:
adjusting a data sampling rate of the memory system based at least in part on the timing parameter.

5. A method by a memory system, comprising:
determining, via a plurality of temperature sensors of an interface die of the memory system, that a first temperature of the memory system satisfies a temperature threshold, wherein the plurality of temperature sensors are distributed across a plurality of regions of the interface die, and wherein the first temperature corresponds to at least one region of the plurality of regions;
transmitting, to a controller of the memory system, an indication that the first temperature of the at least one region satisfies the temperature threshold based at least in part on determining that the first temperature satisfies the temperature threshold; and
adjusting one or more parameters associated with the plurality of regions to reduce the first temperature below the temperature threshold based at least in part on outputting the indication.

6. The method of claim 5, further comprising:
writing, to a register of the memory system, one or more values associated with the first temperature of the memory system, wherein transmitting the indication is based at least in part on writing the one or more values to the register.

7. The method of claim 6, wherein writing the one or more values to the register of the memory system comprises:
determining, via the plurality of temperature sensors, that a plurality of second temperatures of the memory system are each above a respective lower temperature threshold and below a respective upper temperature threshold; and
writing, to the register of the memory system, a single value corresponding to the plurality of second temperatures based on the plurality of second temperatures being above the respective lower temperature threshold and below the respective upper temperature threshold.

8. The method of claim 6, wherein writing the one or more values to the register of the memory system comprises:
determining, via the plurality of temperature sensors, that a second temperature of the memory system is different than the first temperature by a threshold difference, wherein the second temperature corresponds to at least a second region of the interface die; and
writing, to the register of the memory system, a value indicating a difference between the first temperature and the second temperature.

9. The method of claim 5, further comprising:
determining, via the plurality of temperature sensors, that a second temperature of the memory system satisfies the temperature threshold, wherein the second temperature corresponds to a second region of the plurality of regions, and wherein the indication further indicates the at least one region corresponds to the first temperature and the second region corresponding to the second temperature.

10. The method of claim 5, further comprising:
determining that a rate of change of the first temperature satisfies a temperature change rate threshold, wherein transmitting the indication is based at least in part on the rate of change of the first temperature satisfying the temperature change rate threshold.

11. The method of claim 5, wherein adjusting the one or more parameters associated with the plurality of regions comprises:
deactivating a first set of voltage rails associated the at least one region; and
activating a second set of voltage rails associated with at least a second region, wherein deactivating the first set of voltage rails and activating the second set of voltage rails is associated with reducing the first temperature.

12. The method of claim 5, wherein the temperature threshold comprises a maximum temperature of the interface die during a duration of time.

13. A method by a memory system, comprising:
receiving a write command for writing first data to a first memory die of the memory system;
determining, via a first plurality of temperature sensors of an interface die of the memory system and a second temperature sensor of the first memory die of the memory system, whether a first temperature or a second temperature of the memory system satisfy a temperature threshold, wherein the first plurality of temperature sensors are distributed across a plurality of regions of the interface die, and wherein the first temperature corresponds to at least one region of the plurality of regions, and wherein the second temperature corresponds to the first memory die;
transmitting, to a controller of the memory system, an indication that the second temperature satisfies the temperature threshold based at least in part on determining that the second temperature satisfies the temperature threshold;
refraining from writing the first data to the first memory die based at least in part on transmitting the indication that the second temperature satisfies the temperature threshold; and
writing the first data to a second memory die of the memory system based at least in part on refraining from writing the first data to the first memory die.

14. The method of claim 13, further comprising:
transmitting an indication that the second temperature satisfies the temperature threshold based at least in part on determining that the second temperature satisfies the temperature threshold; and
receiving an updated write command for writing the first data to the second memory die of the memory system, wherein writing the first data to the second memory die of the memory system is based at least in part on receiving the updated write command.

15. The method of claim 13, further comprising:
receiving a second write command for writing second data to the first memory die of the memory system;
determining, via the first plurality of temperature sensors and the second temperature sensor, whether a third temperature or a fourth temperature of the memory system satisfy the temperature threshold, wherein the third temperature corresponds to at least one region of the plurality of regions, and wherein the fourth temperature corresponds to the first memory die;
transmitting, to the controller of the memory system, a second indication that the fourth temperature satisfies the temperature threshold based at least in part on determining that the fourth temperature satisfies the temperature threshold; and
writing the second data to the first memory die at a second frequency that is less than a first frequency used to write the first data to the second memory die.

16. The method of claim 13, further comprising:
adjusting, by the controller, traffic associated with one or more channels of the memory system based at least in part on determining that the first temperature satisfies the temperature threshold.

17. The method of claim 13, further comprising:
transmitting, by the controller, an indication to reduce traffic associated with one or more channels of the memory system based at least in part on determining that the first temperature satisfies the temperature threshold.

18. The method of claim 13, further comprising:
disabling one or more components of the memory system based at least in part on determining that the first temperature, the second temperature, or both satisfy the temperature threshold.

19. The method of claim 13, further comprising:
disabling one or more channels coupled with the interface die and the first memory die of the memory system based at least in part on determining that the first temperature, the second temperature, or both satisfy the temperature threshold.

20. The method of claim 13, further comprising:
reducing an operating frequency of one or more channels coupled with the interface die and the first memory die of the memory system based at least in part on determining that the first temperature, the second temperature, or both satisfy the temperature threshold.

21. A memory system comprising:
an interface die that comprises a plurality of regions;
a first plurality of temperature sensors distributed across the plurality of regions, wherein the first plurality of temperature sensors are configured to obtain a temperature of a respective region of the interface die;
a first memory die coupled with the interface die; and
a second temperature sensor located on the first memory die.

22. The memory system of claim 21, wherein:
a first temperature sensor and a second temperature sensor of the first plurality of temperature sensors are aligned along a first boundary of the interface die;
a third temperature sensor and a fourth temperature sensor of the first plurality of temperature sensors are aligned along a second boundary of the interface die; and
the first temperature sensor, the third temperature sensor, and a fifth temperature sensor of the first plurality of temperature sensors are aligned colinearly.

23. The memory system of claim 22, further comprising:
a plurality of data channels coupled with the interface die and the first memory die, wherein a first subset of the plurality of data channels is located between the first temperature sensor and the fifth temperature sensor, and a second subset of the plurality of data channels is located between the fifth temperature sensor and the third temperature sensor.

24. The memory system of claim 21, further comprising:
a plurality of stacked memory dies above the first memory die, wherein each memory die of the plurality of stacked memory dies includes a respective temperature sensor.
